(19) United States
(12) Patent Application Publication
(10) Pub. No.: US 2010/0157690 A1
(43) Pub. Date: Jun. 24, 2010

(54) Semiconductor Memory Device of Single Gate Structure

(76) Inventor: Jin Hyo JUNG, Suwon-si (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/638,848

(22) Filed: Dec. 15, 2009

(30) Foreign Application Priority Data
Dec. 22, 2008 (KR) 10-2008-0131552

(51) Int. Cl. G11C 16/14; H01L 29/788; G11C 16/12; G11C 16/26

(52) U.S. Cl. 365/185.29; 257/315; 365/185.18; 257/E29.305

(57) ABSTRACT

A single gate semiconductor memory device includes a high-potential well on an upper portion of a semiconductor substrate; a first well on an upper portion of the high potential second conductive type well; a second well spaced apart from the first well on the upper portion of the high potential well and across the high-potential well; a floating gate on the first well and the second well; a first ion implantation region in the first well on one side of the floating gate; a second ion implantation region in the first well on an opposite side of the floating gate; a first complementary ion implantation region in the first well next to the second ion implantation region; a third ion implantation region in the second well on one side of the floating gate; and a second complementary ion implantation region in the second well on the opposite side of the floating gate.

### CROSS-REFERENCE TO RELATED APPLICATION

This application claims the benefit under 35 U.S.C. §119 of Korean Patent Application No. 10-2008-0131552, filed on Dec. 22, 2008, which is incorporated herein by reference in its entirety.

### BACKGROUND

### Description of the Related Art

Embodiments of the present invention relate to a semiconductor memory device having a single gate structure.

Generally, a semiconductor memory device such as an electrically erasable programmable read only memory (EEPROM) has a multi-layer structure where a floating gate, an oxide-nitride-oxide (ONO) layer, and a control gate are stacked. However, single gate memory device structures, having a relatively simple manufacturing process and excellent operation characteristics, have been recently studied.

FIG. 1A is a diagram showing applied voltage(s) when programming a typical single gate semiconductor memory device. In the following description, the above-mentioned semiconductor memory device is considered to be an EEPROM.

The semiconductor memory device is programmed by hot channel electron injection, and when a programming voltage is applied to an N-well 10 (operated as a control gate), a specific voltage may be induced by a coupling ratio of the floating gate (s) 20.

The voltage induced on the floating gate 20 inverts a potential of the channel area of an NMOS device 30 and when a predetermined voltage (e.g., VDS) is applied to the drain 31 of the NMOS device 30, current flows from the drain 31 to the source 32 of the NMOS device 30. Therefore, hot channel electrons generated near a junction area of the drain 31 are injected into the floating gate 20, such that a threshold voltage of the NMOS device 30 may increase.

FIG. 1B is a diagram showing applied voltage(s) when erasing data of the typical single gate semiconductor memory device.

The data erase operation of the semiconductor memory device is performed by Fowler-Nordheim (F/N) tunneling, which grounds the N-well 10 and applies an erase voltage (e.g., +VE) to the source 32 and drain 31 of the NMOS device 30. When the ground potential is applied to the N-well 10, a voltage close to the ground level is induced on the floating gate 20, and an electric field is strongly applied from the source 32 and drain 31 to the floating gate 20 by an erasing voltage (+VE) applied to the source 32 and drain 31. The electric field causes F/N tunneling, and electrons in the floating gate 20 are discharged to the source 32 and/or drain 31, reducing the threshold voltage of the NMOS device 30.

FIG. 1C is a diagram showing applied voltage(s) when reading the data of the typical single gate semiconductor memory device.

When a reading voltage (+VR) is applied to the N-well 10, a specific voltage may be induced on the floating gate 20. In addition, a positive drain voltage for the reading operation is applied to the drain 31 of the NMOS device 30, and the source 32 is grounded. When electrons are injected into the floating gate 20 and the threshold voltage of the NMOS DEVICE 30 is in a high program state, the specific voltage induced on the floating gate 20 cannot turn on the NMOS device 30, and a current does not flow.

Further, when electrons are discharged from the floating gate 20 and the threshold voltage of the NMOS device 30 is in a low state, the specific voltage induced on the floating gate 20 can turn on the NMOS device 30, and a current flows. Therefore, the data can be read in some cases.

In the above-mentioned single gate semiconductor memory device, a P-well 40, in which the NMOS device 30 is formed, is electrically connected to a semiconductor substrate.

Although not shown in the drawings, predetermined circuit devices are formed in other areas on the semiconductor substrate. At this time, when the semiconductor substrate is biased to a specific negative potential, the semiconductor memory device may not operate.

There is a method of forming a Deep N-well that separates the P-well from the semiconductor substrate in order to operate the single gate semiconductor memory device when the semiconductor substrate is biased to negative potential. However, the N-well 10, which performs a role of a word line in the single gate semiconductor memory device, should be separated from the Deep N-well. As a result, it may be difficult to implement the single gate semiconductor memory device, and the operation thereof may be unstable or unreliable.

### SUMMARY OF THE INVENTION

An object of the invention is to provide a single gate semiconductor memory device that can be formed in a semiconductor substrate of negative potential without adopting a p-well separation structure or another separation structure such as an N-well and a deep N-well, etc., at least one of which may operate as a word line when a semiconductor substrate is biased to negative potential.

A semiconductor memory device according to embodiments of the invention may include a high-potential well on an upper portion of a semiconductor substrate; a first well on an upper portion of the high potential well; a second well spaced apart from the first well on the upper portion of the high potential well and across the high-potential well; a floating gate on the first well and the second well; a first ion implantation region in the first well region on one side of the floating gate; a second ion implantation region in the first well region on an opposite side of the floating gate; a first complementary ion implantation region in the first well next to the second ion implantation region; a third ion implantation region in the second well on the opposite side of the floating gate; and a second complementary ion implantation region in the second well on the opposite side of the floating gate. The first and second wells and the first and second complementary ion implantation regions may have a first conductive type, and the high-potential well and the first, second and third ion implantation regions may have the second conductive type.

A single gate semiconductor memory device according to other embodiments may include a high-potential well on an upper portion of a semiconductor substrate; a first well on an upper portion of the high potential well; a second well spaced apart from the first well on the upper portion of the high potential well; a floating gate on the first well and the second well; a first ion implantation region in the first well on one side of the floating gate; a second ion implantation region in the first well on an opposite side of the floating gate; a first complementary ion implantation region in the first well next to the second ion implantation region; a third ion implantation region in the second well next to the floating gate; and a second ion implantation region in the second well spaced apart from the floating gate by the third ion implantation region.

### BRIEF DESCRIPTION OF THE DRAWINGS

FIG. 1a is a diagram showing applied voltages when programming a general single gate semiconductor memory device;

FIG. 1b is a diagram showing applied voltages when erasing data of the general single gate semiconductor memory device;

FIG. 1c is a diagram showing applied voltages when reading data of the general single gate semiconductor memory device;

FIG. 2 is a top view showing a single gate semiconductor memory device structure according to a first embodiment;

FIG. 3 is a cross-sectional view showing a structure of the semiconductor memory device according to the first embodiment based on line A-A′ of FIG. 2;

FIG. 4 is a cross-sectional view showing the structure of the semiconductor memory device according to the first embodiment based on line B-B′ of FIG. 2;

FIG. 5 is a cross-sectional view showing the structure of the semiconductor memory device according to the first embodiment based on line C-C′ of FIG. 2;

FIG. 6 is a top view showing a single gate semiconductor memory device structure according to a second embodiment;

FIG. 7 is a cross-sectional view showing a structure of the semiconductor memory device according to the second embodiment based on line A-A′ of FIG. 6;

FIG. 8 is a cross-sectional view showing the structure of the semiconductor memory device according to the second embodiment based on line B-B′ of FIG. 6;

FIG. 9 is a cross-sectional view showing a structure of the semiconductor memory device according to the second embodiment based on line C-C′ of FIG. 6; and

FIG. 10 is a graph measuring characteristics of an applied voltage and a threshold voltage when programming and erasing the single gate semiconductor memory device according to an embodiment.

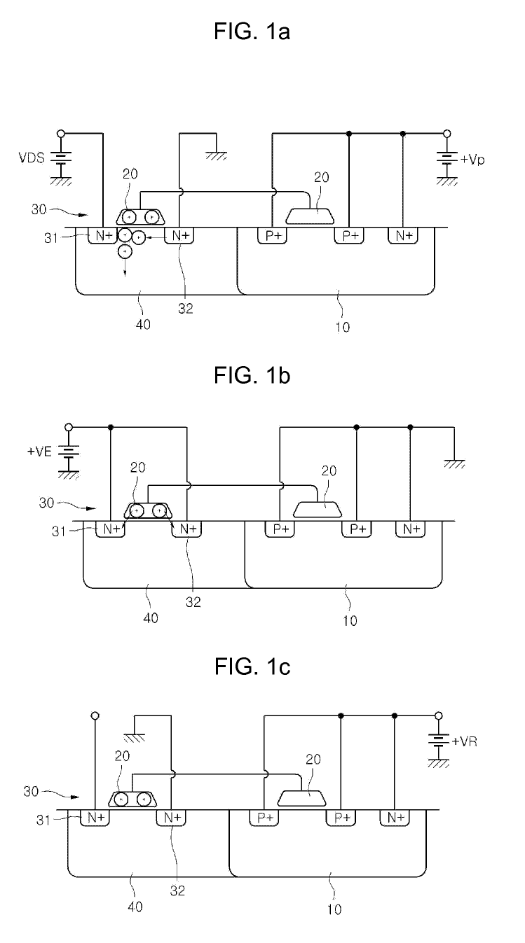

### DETAILED DESCRIPTION OF THE EMBODIMENTS

A single gate semiconductor memory device according to embodiments will be described in more detail with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

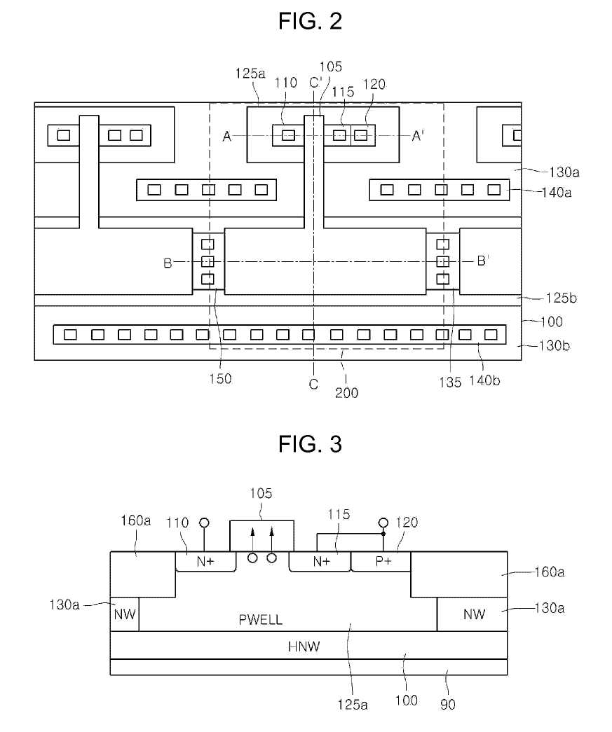

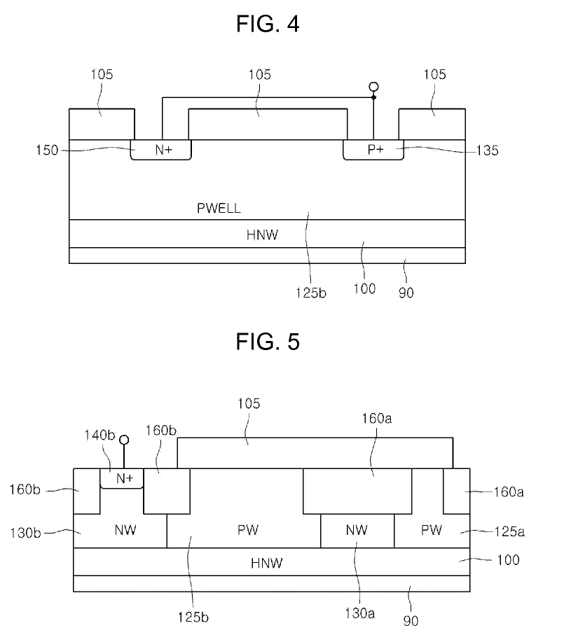

FIG. 2 is a top view of a single gate semiconductor memory device according to a first embodiment, and FIG. 3 is a cross-sectional view showing a structure of the single gate semiconductor memory device according to the first embodiment based on line A-A′ of FIG. 2. Also, FIG. 4 is a cross-sectional view showing the structure of the single gate semiconductor memory device according to the first embodiment based on line B-B′ of FIG. 2, and FIG. 5 is a cross-sectional view showing the structure of the single gate semiconductor memory device according to the first embodiment based on line C-C′ of FIG. 2

Hereinafter, the semiconductor memory device according to the first embodiment will be described with reference to FIGS. 2 to 5. The semiconductor memory device according to the first embodiment may be an EEPROM device.

The semiconductor memory device according to the first embodiment is configured to include a semiconductor substrate 90, a high-potential well 100, a first well 125a having a first conductive type, a second well 125b having the first conductive type, a floating gate 105, a first ion implantation region 110 having a second conductive type, a second ion implantation region 115 having the second conductive type, a first complementary ion implantation region 120 having the first conductive type, a third ion implantation region 150 having the second conductive type, a second complementary ion implantation region 135 having the first conductive type, wells 130a and 130b, and tap regions 140a and 140b. In one embodiment, the high-potential well 100 has a second conductive type.

In FIG. 2, a region represented by reference numeral “200” indicates a unit cell of the semiconductor memory device according to the first embodiment.

Hereinafter, for convenience of explanation, high-potential well 100, first well 125a, second well 125b, first ion implantation region 110, second ion implantation region 115, first complementary ion implantation region 120, a third ion implantation region 150, a second complementary ion implantation region 135, and wells 130a and 130b may be referred to as a “high-voltage N type well (HNW) 100”, a “first P well 125a”, a “second P well 125b”, a “first N region 110”, a “second N region 115”, a “first P region 120”, a “third N region 150”, a “second P region 135”, and “N wells 130a and 130b”. In the following description, the first conductive type means a P type and the second conductive type means an N type, but can be understood as a type opposite thereto.

The HNW 100 is formed over the entire surface of the semiconductor substrate 90 (for example, the upper portion of the P type semiconductor substrate), and the first P well 125a, the second P well 125b, and the N wells 130a and 130b are formed in the upper portion of the HNW 100 (that is, the surface of the semiconductor substrate 90 and/or the HNW 100).

The N well 130a is formed around the circumference of the first P well 125a and between the first P well 125a and the second P well 125b, such that the first P well 125a is isolated by the N well 130a.

The second P well 125b is separated from the first P well 125a on the upper portion of the HNW 100 and is formed above the HNW 100 across the semiconductor substrate 90. Therefore, on one side of the second P well 125b (the upper side based on FIG. 2) is the N well 130a and on the opposite side of the second P well 125b (the lower side based on FIG. 2) is the N well 130b. In other words, the N well may be split into two portions 130a and 130b by the second P well 125b.

In one embodiment, the N wells 130a and 130b can be replaced with the HNW 100. In this case, configuration layers formed in the N wells 130a and 130b can be formed in the HNW 100.

The floating gate 105 is formed on the semiconductor substrate on the first P well 125a, and the second P well 125b. The floating gates 105 may each have a T-shape, one linear part of which intersects the first P well 125a, and the orthogonal part of which is parallel with and over the second P well 125b. In other words, the portion of the floating gate 105 on the first P well 125a passes over the first portion 130a of the N well and is connected with the portion of the floating gate 105 on the second P well 125b. Referring to FIG. 2, the vertical portion of the floating gate 105 has a length sufficient to cross over N well 130a, the channel between ion implantation regions 110 and 115, the portion of P well 125a between ion implantation regions 110 and 115 and N well 130a, and part of the P well 125a on the opposite side of ion implantation regions 110 and 115 from P well 125b. The vertical portion of the floating gate 105 has a width about equal to a critical dimension of the technology used to manufacture the semiconductor memory device. The horizontal portion of the floating gate 105 may have a length of from 0.5 to 2 times (e.g., from about 0.8 to about 1.25 times, or any other range of values therein) the length of the vertical portion of the floating gate 105. The horizontal portion of the floating gate 105 may have a width about equal to the width of P well 125a, minus at least four times the standard margin of error of the photolithography equipment used to manufacture the semiconductor memory device. The edges of the horizontal portion of the floating gate 105 closest to the borders of P well 125a may be spaced away from the borders of P well 125a by at least two times the standard margin of error of the photolithography equipment used to manufacture the semiconductor memory device.

The floating gate 105 may be formed on the semiconductor substrate 90 by processes such as forming a gate dielectric layer on the semiconductor substrate 90, depositing a polysilicon layer thereon, patterning a photoresist, etching the polysilicon layer, and removing the photoresist.

The first N region 110 is formed in a part of the first P well 125a on one side of the floating gate 105 (e.g., the vertical portion in FIG. 2), and the second N region 115 is formed in a part of the first P well 125a on the opposite side of the floating gate 105. Further, the first P region 120 is formed in a part of the first P well 125a next to the second N region 115.

Meanwhile, the third N region 150 is formed in a part of the second P well 125b on one side of the floating gate 105 (e.g., the horizontal portion in FIG. 2) and the second P region 135 is formed in a part of the second P well 125b on the opposite side of the floating gate 105.

In one embodiment, the first P well 125a defines a region that operates as an NMOS device, controlling the programming, erasing, and reading of the semiconductor memory device, and the second P well 125b defines a region that operates as a control gate.

For example, the first N region 110 and the second N region 115 function as the source and drain of the NMOS device, and the first P region 120 can perform a function that stabilizes the potential of the NMOS. For reference, the first P region 120 and the second N region 115 may contact each other or may be separated at a predetermined interval.

With the above structure, when the unit cell 200 forms an array, a plurality of first P wells 125a may be spaced apart by the N well 130a, while the second P well 125b can be commonly used, straight across a row or column of cells in the array, without dividing each unit cell 200. In other words, as shown in FIG. 2, the floating gate 105, the third N region 150, and the second P region 135, which forms a part of the unit cell 200, may be repeated across the array in the second P well 125b.

The tap regions 140a and 140b are formed in the N wells 130a and 130b. The N wells 130a and 130b are spaced apart (e.g., into two portions) by the second P well 125b such that the one or more of each of the tap regions 140a and 140b may also be formed in the first N well portion 130a and the second N well portion 130b, respectively. The tap regions 140a and 140b maintain the potential of the N wells 130a and 130b and the HNW 100 at a predetermined numerical value.

FIG. 2 is a top view showing a form of the semiconductor memory device according to an embodiment in which device isolation layers 160a and 160b are excluded. As shown in FIGS. 3 to 5, the device isolation layers 160a and 160b are formed in the upper portion (surface) of the semiconductor substrate 90 and may surround the tap regions 140a and 140b, the first N region 110 and the first P region 120, and/or the P wells 125a and/or 125b.

The device isolation layers 160a and 160b can be characterized as a first portion 160a that covers the N well 130a and a part of the first P well 125a, and a second portion 160b that covers the N well 130b and a part of the second P well 125b.

As described above, the semiconductor substrate 90 and the configuration layers 125a, 125b, 110, 115, 120, 150, 135, 130a, and 130b in the upper portion of the semiconductor substrate 90 can be completely separated by the HNW 100, which does not affect the operation of the memory device even though the semiconductor substrate 90 is biased to a negative potential.

Hereinafter, the operations of the programming, erasing, and reading of the single poly semiconductor memory device according to the first embodiment will be described as follows.

First, when programming the single poly semiconductor memory device according to the first embodiment, a first voltage (+Vp: program voltage) of positive potential is applied to the second P region 135, the third N region 150, the tap regions 140a and 140b (used as the word line), and the first N region 110, the second N region 115, and the first P region 120 are grounded (e.g., by applying a potential of 0V). Alternatively, the second P region 135, the third N region 150, and the tap regions 140a and 140b can be grounded, and a first voltage (−Vp) of negative potential may be applied to the first N region 110, the second N region 115, and the first P region 120. In either case, in further embodiments, the first N region 110 may be floating.

For example, voltage of about −10V may be applied to the semiconductor substrate 90 and voltage of +18V may be applied to the HNW 100. Further, the first voltage may be about ±18V.

With these bias conditions, the first voltage applied to the second P well 125b (operating as a control gate) is induced onto the floating gate 105 on the first P well 125a by a coupling phenomenon. If the first voltage is induced to the first P well 125a side, it may change into a second voltage by the coupling phenomenon.

Therefore, a strong electromagnetic field is formed between the first P well 125a and the floating gate 105 to which the second voltage is induced, and electrons in the first P well 125a can be injected to the floating gate 105 by F/N tunneling. As a result, the threshold voltage of the NMOS region (that is, the first P well 125a region) increases and the programming operation can be performed.

Second, when erasing the semiconductor memory device according to the first embodiment, the second P region 135 and the third N region 150 (used as the word line) are grounded (e.g., by applying a potential of 0V), and a third voltage (+Ve: erase voltage) of positive potential is applied to the first N region 110, the second N region 115, the first P region 120, and the tap regions 140a and 140b. Alternatively, a third voltage (−Ve) of negative potential may be applied to the second P region 135 and the third N region 150, and the first N region 110, the second N region 115, the first P region 120, and the tap regions 140a and 140b may be grounded. In either case, in further embodiments, the first N region 110 may be floating.

With these bias conditions, a ground potential (e.g., 0V) applied to the second P well 125b (which operates as the control gate) is induced to the floating gate 105 over the first P well 125a by the coupling phenomenon. Therefore, a strong electromagnetic field is formed between the first P well 125a and the floating gate 105 to which the second voltage is induced, and electrons stored on the floating gate 105 thus exit to the first P well 125a.

Therefore, the threshold voltage of the NMOS region (that is, the first P well 125a region) is reduced, and the erasing operation can be performed.

Third, when reading the semiconductor memory device according to the first embodiment, a fourth voltage (+Vcgr: control gate reading voltage) of positive potential is applied to the second P region 135, the third N region 150, and the tap regions 140a and 140b (used as the word line), and a fifth voltage (+Vdr: drain voltage) of positive potential is applied to the first N region 110. Further, a ground potential (e.g., 0V) is applied to the second region 115 and the first P region 120.

With these bias conditions, the fourth voltage applied to the second P well 125b (which operates as the control gate) is induced to the floating gate 105 over the first P well 125a by the coupling phenomenon. If the fourth voltage is induced to the first P well 125a side, it changes into a sixth voltage of specific potential by the coupling phenomenon.

At this time, when the semiconductor memory device according to the first embodiment is in the programmed state, the sixth voltage induced to the floating gate 105 is lower than the threshold voltage in the programmed state and thus turns off the NMOS device of the first P well 125a. Therefore, current does not flow.

In addition, when the semiconductor memory device according to the first embodiment is in the erased state, the sixth voltage induced to the floating gate 105 is higher than the threshold voltage in the programming state and thus turns on the NMOS device of the first P well 125a. Therefore, current flows from the second N region 115 (source) to the first N region 110 (drain). Therefore, the reading operation can be performed according to each case.

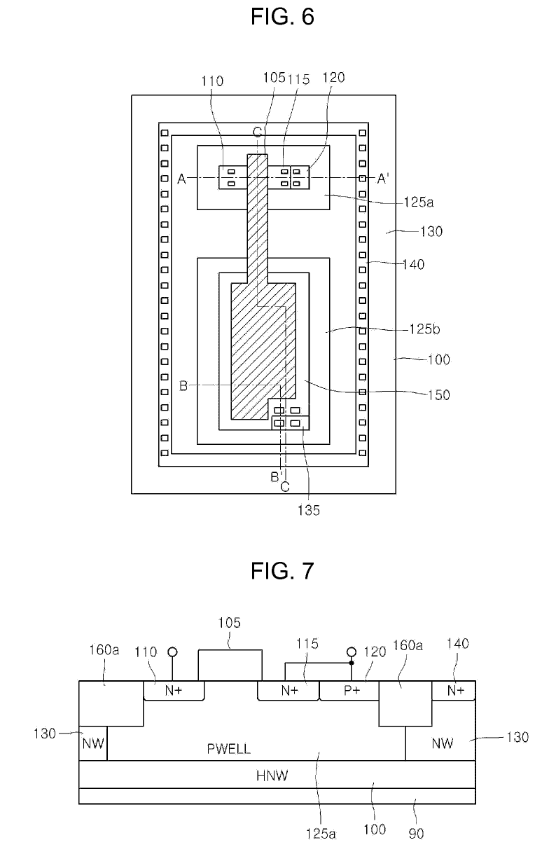

The single gate semiconductor memory device according to a second embodiment will be described with reference to FIGS. 6 to 9. The semiconductor memory device according to the second embodiment may be considered to be an EEPROM device.

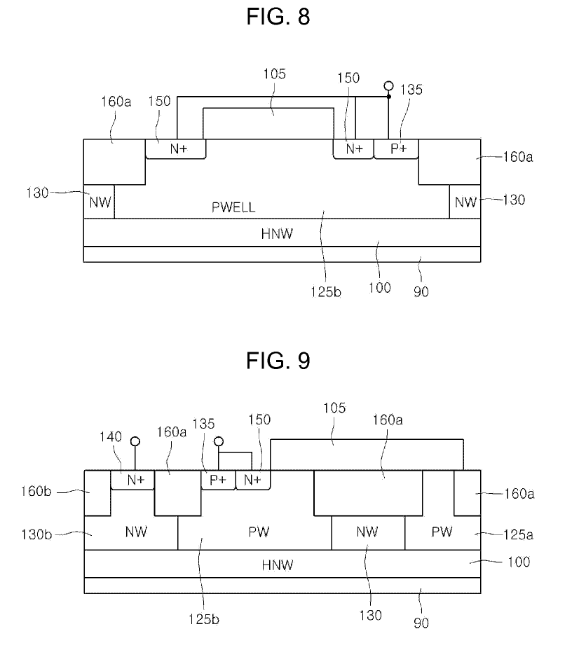

FIG. 6 is a top view showing a single gate semiconductor memory device according to a second embodiment, and FIG. 7 is a cross-sectional view showing a structure of the semiconductor memory device according to the second embodiment based on line A-A′ of FIG. 6. FIG. 8 is a cross-sectional view showing the structure of the semiconductor memory device according to the second embodiment based on line B-B′ of FIG. 6, and FIG. 9 is a cross-sectional view showing a structure of the semiconductor memory device according to the second embodiment based on line C-C′ of FIG. 6.

The semiconductor memory device according to the second embodiment is configured to include the semiconductor substrate 90, the high-potential well 100, the first well 125a, the second well 125b, the floating gate 105, the first ion implantation region 110, the second ion implantation region 115, the first complementary ion implantation region 120, the third ion implantation region 150, the second complementary ion implantation region 135, a well 130, and tap region 140. The first well 125a, the second well 125b, and the first and second complementary ion implantation region 120 and 135 may have a first conductivity type, and the high-potential well 100, the first, second and third ion implantation regions 110, 115 and 150, and the well 130 may have a second conductivity type.

The second embodiment shown in FIG. 6 shows only a portion of the structures corresponding to the unit cell 200 of the first embodiment.

Hereinafter, for convenience of explanation, the high-potential well 100, the first well 125a, the second well 125b, the first ion implantation region 110, the second ion implantation region 115, the first complementary ion implantation region 120, the third ion implantation region 150, the second complementary ion implantation region 135, and the well 130 may be referred to as the “high-voltage N type well (HNW) 100”, the “first P well 125a”, the “second P well 125b”, the “first N region 110”, the “second N region 115”, the “first P region 120”, the “third N region 150”, the “second P region 135”, and “the N well 130a”.

In the following description, the first conductive type means a P type and the second conductive type means an N type, but can be understood as a type opposite thereto.

The semiconductor memory device according to the second embodiment has a structure approximately similar to the first embodiment and therefore, only the differences therebetween will be described.

First, in the first embodiment, the second P well 125b may be formed on or above the HNW 100 across a row or column of the array, but in the second embodiment, the second P well 125b is spaced apart from the first P well 125a on the upper portion of the HNW 100 and is isolated by the N well 130. That is, the N well 130 of the second embodiment surrounds (e.g., is at the circumference of) each of the second P well 125b and the first P well 125a, and is not spaced in two portions 130a and 130b by the second P well 125b as in the first embodiment.

In the second embodiment, the N well 130 can be replaced with the HNW 100. In this case, configuration layers in the N well 130 can be formed in the HNW 100.

Second, when the unit cell 200 forms an array, the plurality of first P wells 125a and second P wells 125b are separated by the N well 130. In other words, in the second embodiment, the second P well 125b, which has a straight form in the first embodiment, is not common to each unit cell 200, and is divided and or separated in each cell unit in the second embodiment.

In the case of the first embodiment, the second P well 125b is common to adjacent cell units in a row or column of the memory array. As a result, the first embodiment may be advantageous in reducing the chip size. On the other hand, in the case of the second embodiment, the second P well 125b is enclosed within the cell unit. As a result, the second embodiment may be advantageous in operation.

Third, the second embodiment may not form a structure in which the floating gate 105, the third N region 150, and the second P region 135, which form part of the unit cell 200, is repeated in the second P well 125b. Therefore, a degree of freedom can be secured regarding the location where the third N region 150 and the second P region 135 of the second embodiment are formed. For example, the third N region 150 may be formed at any place adjacent or next to the second P well 125b that is next to the floating gate 105 or along the circumference of the floating gate 105 as shown in FIG. 6.

Further, the second P region 135 may be formed in the second P well 125b next to the third N region 150 and may be spaced apart from the floating gate 105.

Fourth, the tap region 140 according to the second embodiment is formed in the N well 130, and therefore, may an integrated region or structure. For example, the tap region 140 according to the second embodiment is formed in the upper portion of the N well 130 as shown in FIG. 6 and may be in a ring surrounding the first P well 125a and the second P well 125b.

Fifth, FIG. 6 shows a top view of the semiconductor memory device according to the second embodiment in which the device isolation layers 160a and 160b are excluded. As shown in FIGS. 7 to 9, the device isolation layers 160a and 160b are formed in the upper portion (surface) of the semiconductor substrate 90, around or adjacent to the tap region 140, the first N region 110, the first P region 120, the third N region 150, and the second P region 135.

The device isolation layers 160a and 160b are not divided into two portions by the second P well 125b. They may be integrated within the tap region 140. However, the device isolation layers 160a and 160b may be divided into two portions 160a and 160b on the inner side and outer side of the tap region 140.

The operations of programming, erasing, and reading the single gate semiconductor memory device according to the second embodiment are the same as the first embodiment (i.e., the applied bias voltages are identical), and therefore, the repeated description thereof will be omitted.

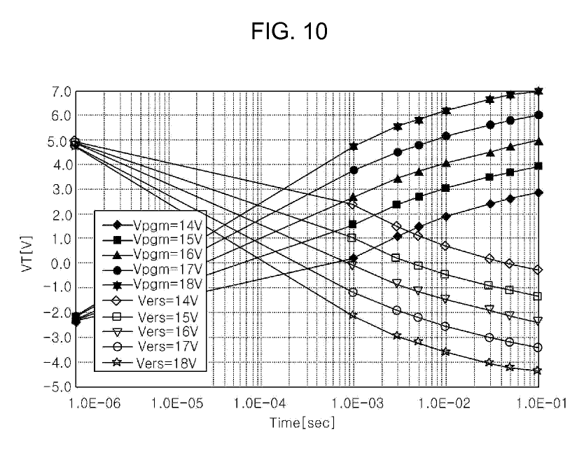

FIG. 10 is a graph measuring characteristics of the applied voltage and the threshold voltage when programming and erasing the semiconductor memory device according an embodiment.

As can be appreciated from the graph of FIG. 10, when the first voltage (+Vp: program voltage) of about 18V is applied for about 10 ms, the NMOS threshold voltage of about 6V or more can be secured and when the third voltage (+Ve: erase voltage) of about 18V is applied for about 10 ms, the NMOS device threshold voltage of about −3.5V or less can be secured. At this time, the fourth voltage (+Vcgr: control gate reading voltage) is applied at about 1.5V. Therefore, in this embodiment, the difference between the NMOS device threshold voltage at the time of the programming operation and the erasing operation can be secured at about 9.5V or more.

With the above embodiments, the following effects can be obtained.

First, the semiconductor memory device can be formed on a semiconductor substrate of negative potential by a simple process without adopting a separation structure between the p-well and the semiconductor substrate, another separation structure such as the N-well and the deep N-well, etc. (which may operate as a word line), when the semiconductor substrate is biased to negative potential.

Second, even though the semiconductor substrate is biased to negative potential, the programming/erasing/reading operations of the semiconductor memory device can be stably conducted.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor memory device, comprising:
a high-potential well on an upper portion of a semiconductor substrate;
a first well on an upper portion of the high potential well, the first well having a first conductive type;
a second well spaced apart from the first well on the upper portion of the high potential well across the high-potential well, the second well having a first conductive type;
a floating gate on the first well and the second well, the floating gate having a first conductive type;
a first ion implantation region in the first well on one side of the floating gate, the first ion implantation region having a second conductive type;
a second ion implantation region in the first well region on an opposite side of the floating gate, the second ion implantation region having the second conductive type;
a first complementary ion implantation region in the first well next to the second ion implantation region, the first complementary ion implantation region having the first conductive type;
a third ion implantation region in the second well region on one side of the floating gate, the third ion implantation region having the second conductive type; and
a second complementary ion implantation region in the second well region on an opposite side of the floating gate.

2. The semiconductor memory device of claim 1, wherein the high-potential well has the second conductive type, and the first well is surrounded on a side surface and a bottom surface by the high-potential well.

3. A semiconductor memory device, comprising:
a high-potential well in an upper portion of a semiconductor substrate;
a first well on an upper portion of the high potential well;
a second well spaced apart from the first well on the upper portion of the high potential well;
a floating gate on the first well and the second well;
a first ion implantation region in the first well region on one side of the floating gate;
a second ion implantation region in the first well on an opposite side of the floating gate;
a first complementary ion implantation region in the first well next to the second ion implantation region;
a third ion implantation region in the second well next to the floating gate; and
a second complementary ion implantation region in the second well region.

4. The semiconductor memory device according to claim 2, further comprising wells in the upper portion of the high-potential well, on side surfaces of the first well and the second well.

5. The semiconductor memory device according to claim 4, further comprising at least one tap region in the upper portion of at least one of the first and second wells.

6. The semiconductor memory device according to claim 5, wherein the tap region is in a ring, surrounding the first well and the second well.

7. The semiconductor memory device according to claim 1, further comprising at least one tap region in an upper portion of the high-potential well, the first well, or the second well.

8. The semiconductor memory device according to claim 3, further comprising a tap region in an upper portion of the high-potential well, in a ring surrounding the first well and the second well.

9. The semiconductor memory device according to claim 5, further comprising a device isolation layer in the upper portion of the semiconductor substrate, adjacent to the tap region, the first ion implantation region, the first complementary ion implantation region, or the second complementary ion implantation region.

10. The semiconductor memory device according to claim 5, wherein the first and second wells and the first and second complementary ion implantation regions have a first conductive type, and the high-potential well, the first, second and third ion implantation regions, and the tap region have a second conductive type.

11. A method of programming the semiconductor memory device according to claim 1, comprising:
applying a first voltage of positive potential to the second ion implantation region and the third ion implantation region, and
grounding the first complementary ion implantation region, the second complementary ion implantation region, and the first ion implantation region.

12. A method of programming the semiconductor memory device according to claim 5, comprising:
applying a first voltage of positive potential to the second ion implantation region, the third ion implantation region, and the tap region, and
grounding the first complementary ion implantation region, the second complementary ion implantation region, and the first ion implantation region.

13. A method of programming the semiconductor memory device according to claim 1, comprising:
grounding the second complementary ion implantation region and the third ion implantation region, and
applying a voltage of negative potential to the first ion implantation region, the second ion implantation region, and the first complementary ion implantation region.

14. A method of programming the semiconductor memory device according to claim 5, comprising:
grounding the second complementary ion implantation region, the third ion implantation region, and the tap region, and
applying a voltage of negative potential to the first ion implantation region, the second ion implantation region, and the first complementary ion implantation region.

15. A method of erasing the semiconductor memory device according to claim 1, comprising:
grounding the second complementary ion implantation region and the third ion implantation region, and
applying an erase voltage of positive potential to the first ion implantation region, the second ion implantation region, and the first complementary ion implantation region.

16. A method of erasing the semiconductor memory device according to claim 5, comprising:
grounding the first conductive type second ion implantation region and the second conductive type third ion implantation region, and
applying an erase voltage of positive potential to the first ion implantation region, the second ion implantation region, the first complementary ion implantation region, and the tap region.

17. A method of erasing the semiconductor memory device according to claim 1, comprising:
applying a negative voltage to the second complementary ion implantation region and the third ion implantation region, and
grounding the first ion implantation region, the second ion implantation region, and the first complementary ion implantation region.

18. A method of erasing the semiconductor memory device according to claim 5, comprising:
applying a negative voltage to the second complementary ion implantation region and the third ion implantation region, and
grounding the first ion implantation region, the second ion implantation region, the first complementary ion implantation region, and the tap region.

19. A method of reading the semiconductor memory device according to claim 1, comprising:
applying a read voltage of positive potential to the second complementary ion implantation region, the third ion implantation region, and the tap region,
applying a positive voltage to the first ion implantation region, and
grounding the second ion implantation region and the first complementary ion implantation region.

20. A method of reading the semiconductor memory device according to claim 5, comprising:
applying a read voltage of positive potential to the second complementary ion implantation region, the third ion implantation region, and the tap region,
applying a positive voltage to the first ion implantation region, and
grounding the second ion implantation region and the first complementary ion implantation region.
